(19) United States
(12) Patent Application Publication
(10) Pub. No.: US 2025/0324532 A1
(43) Pub. Date: Oct. 16, 2025

(54) CARRIER FRAME FOR A PRINTED CIRCUIT BOARD ASSEMBLY

(71) Applicant: DELL PRODUCTS L.P., Round Rock, TX (US)

(72) Inventors: Jean Doglio, Round Rock, TX (US); Jon Isom, Austin, TX (US)

(21) Appl. No.: 18/633,152

(22) Filed: Apr. 11, 2024

(51) Int. Cl. H05K 7/14; G06F 1/20; H05K 7/20

(52) U.S. Cl. CPC H05K 7/1418; G06F 1/206; H05K 7/20336; H05K 7/2039

(57) ABSTRACT

A printed circuit board assembly for an information handling system includes a carrier frame. The carrier frame to hold a system motherboard and other components. The carrier frame includes a main portion, first and second wing portions, and multiple mounting components. The main portion has a top surface and a bottom surface. The first and second wing portions extend from opposite ends of the main portion. The first and second wing portions have the top surface and the bottom surface. The system motherboard and the other components are in physical communication with the top surface. The mounting components extend from the bottom surface and securely and removably connect the carrier frame within the information handling system.

### FIELD OF THE DISCLOSURE

The present disclosure generally relates to information handling systems, and more particularly relates to a carrier frame for a printed circuit board assembly for an information handling system.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A carrier frame for an information handling system includes may hold a system motherboard and other components. The carrier frame includes a main portion, first and second wing portions, and multiple mounting components. The main portion has a top surface and a bottom surface. The first and second wing portions extend from opposite ends of the main portion. The first and second wing portions have the top surface and the bottom surface. The system motherboard and the other components are in physical communication with the top surface. The mounting components extend from the bottom surface and securely and removably connect the carrier frame within the information handling system.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a perspective view of a diagram of an information handling system according to at least one embodiment of the present disclosure;

FIG. 2 is a perspective view of a rear portion of an information handling system according to at least one embodiment of the present disclosure;

FIG. 3 is a diagram of components within an information handling system according to at least one embodiment of the present disclosure;

FIG. 4 is an exploded view of a diagram of components within an information handling system according to at least one embodiment of the present disclosure;

FIG. 5 is perspective view of a carrier frame according to at least one embodiment of the present disclosure;

FIGS. 6-8 are an exploded view of a carrier frame according to at least one embodiment of the present disclosure;

FIG. 9 is a perspective view of a sealing gasket on a portion of a carrier frame according to at least one embodiment of the present disclosure; and

FIG. 10 is a perspective view of a carrier frame within a chassis base of an information handling system according to at least one embodiment of the present disclosure;

FIG. 11 is a cross sectional view of carrier frame within a chassis base of an information handling system according to at least one embodiment of the present disclosure; and

FIG. 12 is an exploded view of a diagram of components within an information handling system according to at least one embodiment of the present disclosure; and

FIG. 13 is perspective view of a portion an information handling system according to at least one embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

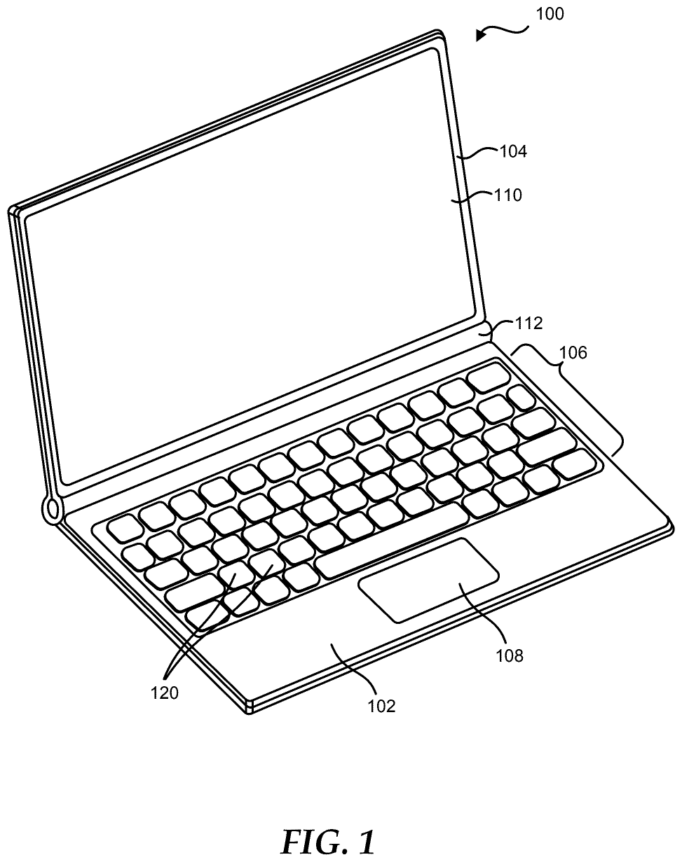

FIG. 1 illustrates an information handling system 100 according to at least one embodiment of the present disclosure. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

Information handling system 100 includes a base portion 102 and a top 104. Base portion 102 includes a keyboard 106 and a touchpad 108, and top portion 104 includes a display device 110. In an example, touchpad 108 may be any suitable pointing device. Base portion 102 is connected top portion 104 via a mechanism 112, such as one or more hinges. Keyboard 106 includes multiple keys 120. When the information handling system 100 comprises a 2-in-1 device, mechanism 112 may enable the top portion 104 to be connected to bottom portion 102 for use as a laptop device and may enable the top portion 104 to be detached from bottom portion 102 to enable the top portion 104 to be used as a tablet information handling system. Display device 110 may include one or more light emitting devices, such as, for example, light emitting diodes (LEDs), organic LED (OLED), liquid crystal display (LCD), another type of light emitting device, or any combination thereof.

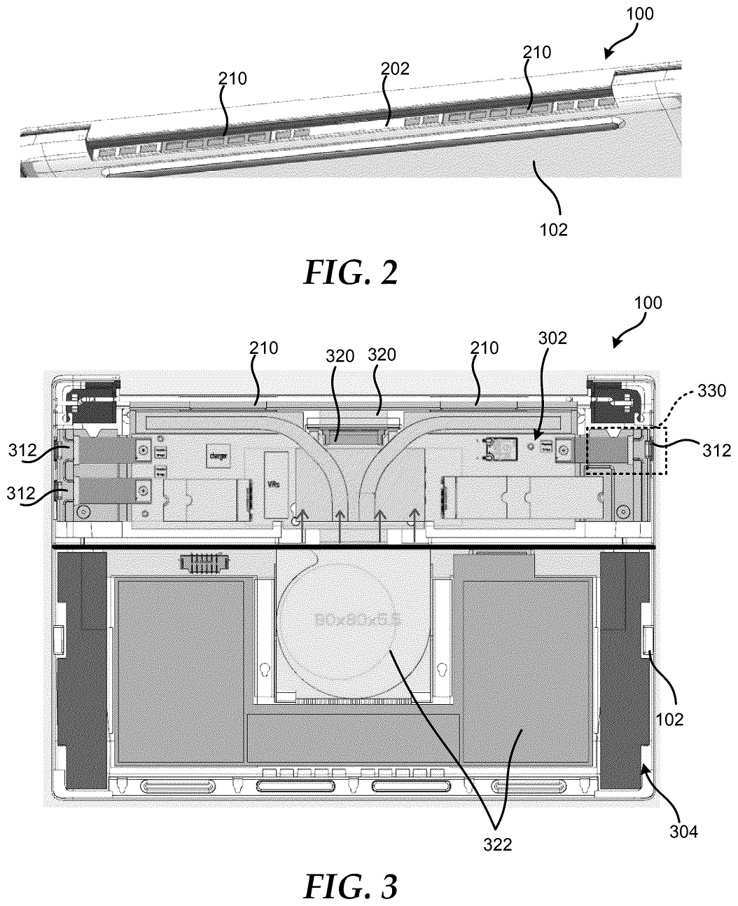

FIG. 2 illustrates a rear portion of information handling system 100 according to at least one embodiment of the present disclosure. Information handling system 100 includes a rear wall 202 and wireless local area network (WLAN) antenna carriers 210. In an example, rear wall 202 may extend upwards from base portion 102. In certain examples, antenna carriers 210 form a portion of rear wall 202. In an example, WLAN antenna carriers 210 may be physically connected to rear wall 202 based on a carrier frame, such as carrier frame 302 of FIG. 3, being inserted within information handling system 100.

FIG. 3 illustrates components within an information handling system according to at least one embodiment of the present disclosure. Information handling system 100 includes carrier frame 302 and a chassis base 304. Carrier frame 302 includes a connector 310, and multiple input/output (IO) connectors 312. Information handling system 100 also includes a connector 320 and other components 322. In an example, other components 322 may be any type of component including, but not limited to, a battery, a cooling fan, and a storage device. Information handling system 100 may include additional components without varying from the scope of this disclosure.

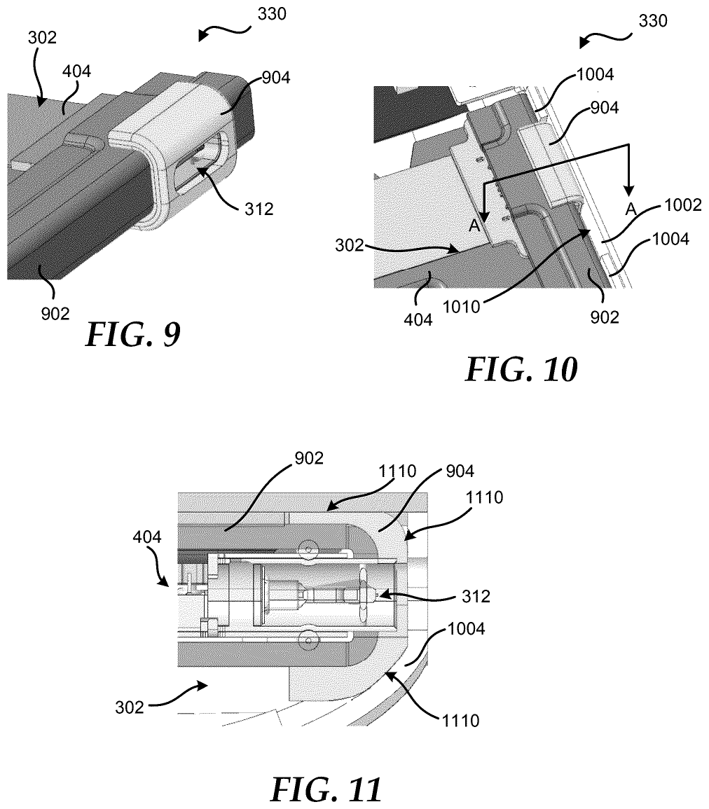

In an example, connectors 310 and 320 may be placed in physical and electrical communication to provide power from a battery located in the chassis base to components on carrier frame 302. In certain examples, connectors 310 and 320 may also enable components on carrier frame 302 to receive signals from and provide signals to components 322 in chassis base 304. Additional details of portion 330 of carrier frame 302 will be described with respect to FIGS. 9 and 10 below.

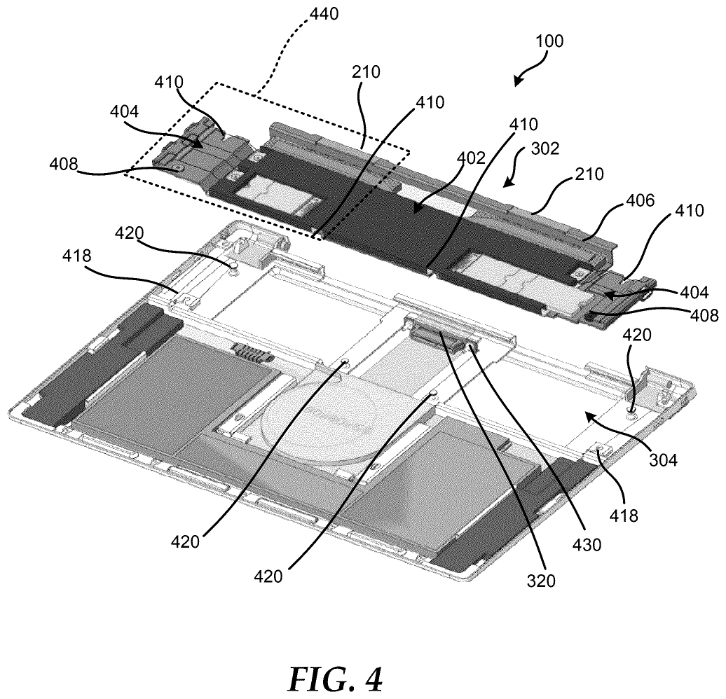

FIG. 4 illustrates a portion of information handling system 100 with carrier frame 302 positioned above chassis base 304 according to at least one embodiment of the present disclosure. Carrier frame 302 includes a main portion 402, wing portions 404, a back wall 406, post mounting components 408, and slot mounting components 410. Chassis base 304 includes slot mounting components 418, post mounting component 420, and connector alignment pins 430. In certain examples, post mounting components 408 and 420 may be any suitable type of post to interlock with corresponding slot mounting components 410 and 418. For example, post mounting components 408 and 420 may be T-nut posts. Information handling system 100 may include additional components without varying from the scope of this disclosure.

In an example, carrier frame 302 may hold a motherboard main printed circuit board assembly (PBCA) and other components for information handling system 100. In certain examples, carrier frame 302 may be a multi-level modular assembly to enable the main PBCA to be a customer removable unit (CRU) and to enable the other components to be field-replaceable units (FRUs) or CRUs. In these examples, carrier frame 302 may enable quick and easy assembly, replacement, or upgrade of the motherboard main PCBA and the other components. This replacement may enable upgrades to a central processing unit (CPU), storage devices, antennas, board layout, and thermal solutions without any changes to the existing chassis 304.

In certain examples, post mounting components 408 and slot mounting components 410 may be positioned at different locations on carrier frame 302. In an example, each of post mounting components 408 may extend from a bottom surface of carrier frame 302. For example, one post mounting component 408 may extend from a front end of the bottom surface of one of wing portions 404, and another post mounting component 408 may extend from a front end of the bottom surface of the other one of wing portions 404. In certain examples, wing portions 404 may extend from opposite ends or sides of main portion 402 as illustrated in FIG. 4.

In an example, each of slot mounting components 410 may be an opening of any particular shape within carrier frame 302. For example, one or more of slot mounting components 410 may include a mouth opening that tapers down to a smaller snap locking portion. Additionally, one or more of slot mounting components 410 may include a large hole through carrier frame 302 and a smaller snap locking hole through the carrier frame. In certain examples, one slot mounting component 410 may be located along a back end of one of wing portions 404, and another slot mounting component 410 may be located along a back end of the other one of wing portions 404. Additionally, multiple slot mounting components 410 may be located along the front edge of main portion 402.

In certain examples, slot mounting components 418 and post mounting components 420 may be positioned at different locations on chassis base 304. In an example, each of slot mounting components 418 may be an opening of any particular shape above chassis base 304. For example, one or more of slot mounting components 418 may include a mouth opening that tapers down to a smaller snap locking portion. Additionally, one or more of slot mounting components 418 may include a large hole and a smaller snap locking hole through. In an example, each of slot mounting components 418 may be within raised portions on the surface of chassis base 304, and a different one of slot mounting components 418 may be positioned substantially below a corresponding different one of post mounting components 408 of carrier frame 302. As illustrated in FIG. 4, two exemplary slot mounting components 418 may be raised above chassis base 304, and each different one of slot mounting components 418 may be located under a corresponding different post mounting component 408 of frame carrier 302.

In an example, each of post mounting components 420 may extend from a surface of chassis base 304, and a different one of post mounting components 420 may be positioned substantially below a corresponding different one of slot mounting components 410 of carrier frame 302. As illustrated in FIG. 4, four exemplary post mounting components 420 may extend upwards from chassis base 304, and each different one of post mounting components 420 may be located under a corresponding different slot mounting component 410 of frame carrier 302.

In certain examples, carrier frame 302 may be connected to chassis base 304 by the carrier frame being lowered down to the chassis base and then pushed towards back wall 202 of the chassis base. As carrier frame 302 is pushed towards back wall 202 of chassis base 304, a different one of post mounting components 408 may interlock with a corresponding different one of slot mounting components 418, and a different one of slot mounting components 410 may interlock with a corresponding different one of post mounting components 420. When carrier frame 302 is interlocked with chassis base 304, antenna carriers 210 may fit within and form part of back wall 202 of the chassis base. Additionally, when carrier frame 302 is interlocked with chassis base 304, wall 406 of carrier frame 302 may be placed in physical communication with back wall 202 of the chassis base.

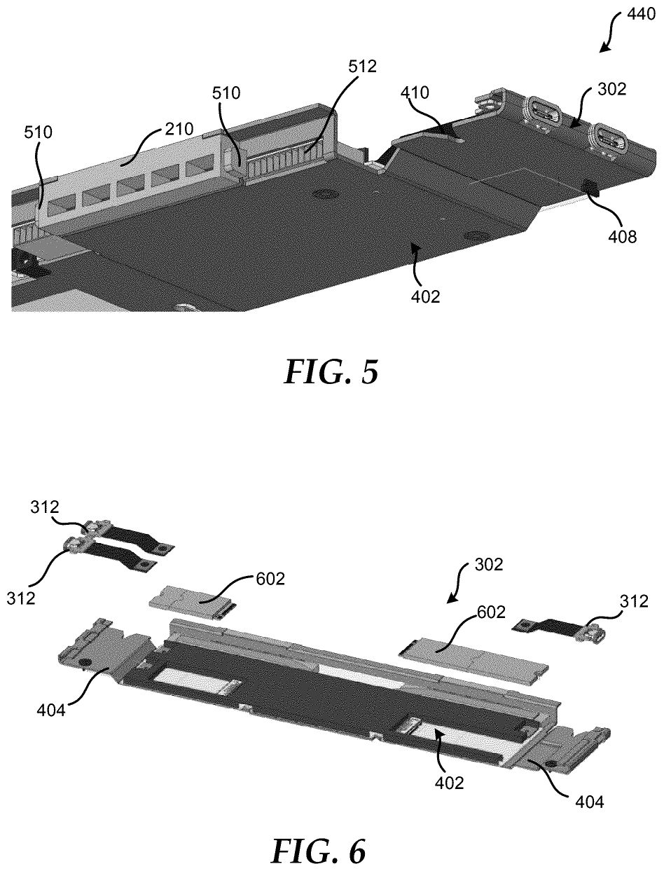

Additionally, alignment pins 430 may ensure that connector 320 is properly aligned with connector 310, shown in FIG. 3, as carrier frame 302 is pushed towards back wall 202 of chassis base 304. In certain examples, the interlocking of post mounting components 408 with slot mounting components 418 and the interlocking of slot mounting components 410 with post mounting components 420 may securely hold carrier frame 302 within chassis base 304. Additionally, the post mounting components 408 and 420 and slot mounting components 410 and 418 may enable tool-less attachment of carrier frame 304 to chassis base 304. A portion 440 of carrier frame 302 will be described with respect to FIG. 5.

FIG. 5 illustrates portion 440 of carrier frame 302 according to at least one embodiment of the present disclosure. Carrier frame 302 includes multiple alignment components 510 in physical communication with antenna carrier 210. For clarity and brevity, only one antenna carrier 210 has been illustrated in FIG. 5 with alignment components 510. However, the other antenna carrier 210, illustrated in FIGS. 2-4, may also include alignment components without varying from the scope of this disclosure. In an example, alignment components 510 may be utilized to align carrier frame 302 with back wall 202 of chassis base 304, shown in FIGS. 2 and 4. In certain examples, alignment components 510 may align carrier frame 302 in the X and Y directions and may snap fit within corresponding components of back wall 202 of chassis base 304, shown in FIGS. 2 and 4.

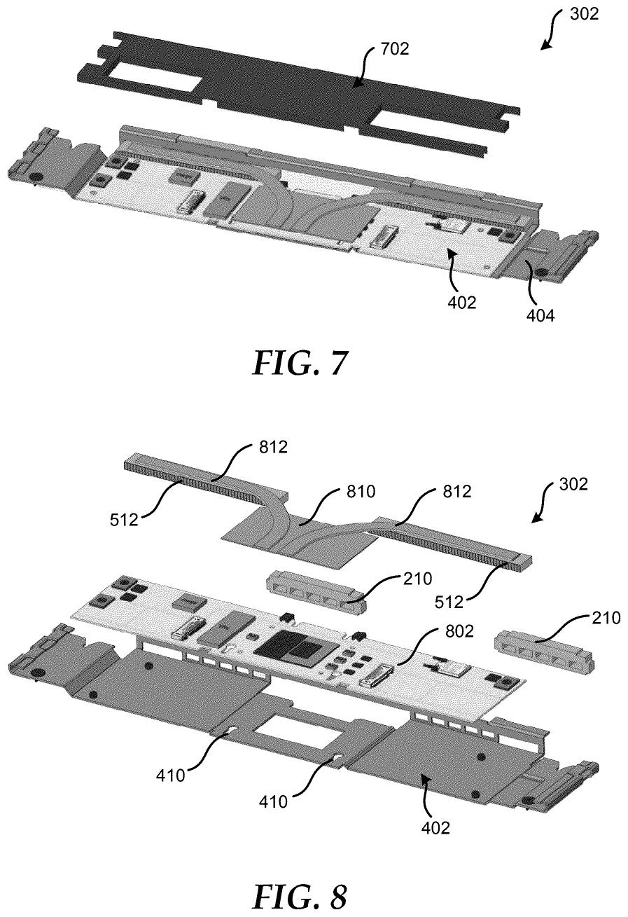

In an example, wall 406 of main portion 402 includes multiple openings to enable an airflow to exit/enter a heat sink 512 of carrier frame 302. In certain examples, carrier frame 302 may include multiple heat sinks 512 as illustrated in FIG. 7 below. Slot mounting component 410 includes a mouth or opening that tapers down to a smaller interlocking portion, and the slot mounting component may extend through wing portion 404. In an example, post mounting component 410 extend downward from the bottom surface of wing portion 404. Post mounting component 408 includes a neck portion and a head portion, and the head portion may be wider than a smaller hole of slot mounting component 418 of chassis base shown in FIG. 4.

FIGS. 6-8 are different exploded views of carrier frame 302 according to at least one embodiment of the present disclosure. Referring to FIG. 6, CRU components on carrier frame 302 are removed from the carrier frame. In an example, the CRU components may include, but are not limited to, memory devices 602, and I/O connectors 312. In certain examples, memory devices 602 may be supported or held by main portion 402 of carrier frame 302. Different ones of I/O connectors 312 may be in physical communication with both main portion 402 and one of wing portions 404.

Referring now to FIG. 7, a removable protective shield 702 has been taken off of carrier frame 302. The removable protective shield 702 may be any suitable material, such as plastic, metal, mylar, or the like. In certain examples, protective shield 702 may physically prevent access to components, such as a solid state device, on carrier frame 302 for security reasons to prevent access to the components by an individual. In an example, protective shield 702 may provide an electromagnet interference/electrostatic discharge (EMI/ESD) barrier. In this example, protective shield 702 may be any suitable material to prevent electrical charges to interfere with the components on carrier frame 302. In an example, removable protective shield 702 may be placed over FRU components that are not meant to be touched during handling/assembly of carrier frame 302. The FRU components covered by removable protective shield 702 are illustrated in FIG. 8.

Referring now to FIG. 8, FRU components on carrier frame 302 are removed from the carrier frame. In an example, the FRU components may include, but are not limited to, a motherboard PCBA 802, a heat removal plate 810, heat pipes 812, heat sinks 512, and antenna carriers 210. Motherboard PCBA 802 may be in physical communication with a top surface of main portion 402, and heat removal plate 810 may be in physical communication with a processor of the motherboard PCBA. In certain examples, heat removal plate 810, heat pipes 812, and heat sinks 512 may combine to transfer heat from motherboard PCBA 802. In an example, different heat removal plate 810, heat pipes 812, and heat sinks 512 may be included on carrier frame 302 based on a CPU utilized in motherboard PCBA 802. In this example, the heat removal plate 810, heat pipes 812, and heat sinks 512 may be customizable and swappable by an individual along with the other components on carrier frame 302. In certain examples, carrier frame 302 may also include one or more cooling fans associated with the CPU of motherboard PCBA 802 and the cooling fans may also be customizable and swappable.

In an example, antenna carriers 210 may be mounted on motherboard PCBA 802 to provide wireless communication for the components of the motherboard PCBA. With motherboard PCBA 802 removed from main portion 402, slot mounting components 410 are visible. As shown in FIG. 8, slot mounting components 412 may be located on a section of main portion 402 that is lower than the other sections of the main portion, such that a post mounting component may interface with the slot mounting component without being placed in physical communication with motherboard PCBA 802.

FIGS. 9-11 illustrate portion 330 of carrier frame 302 according to at least one embodiment of the present disclosure. Carrier frame 302 includes gaskets 902 and 904 attached to wing portion 404. Gaskets 902 and 904 may be any suitable material to protect carrier frame 302 during installation of the carrier frame within a chassis base of an information handling system, such as chassis base 304 of information handling system 100 shown in FIG. 3. For example, gaskets 902 and 904 may be mylar or a similar material. While only a single wing portion 404 is illustrated and described with respect to FIG. 9-11, the other wing portion 404 of carrier frame 302 may include the same features as the wing portion illustrated and described herein.

Referring now to FIG. 9, gasket 902 may wrap around and be in physical communication with the entire length of the end of wing portion 404. In certain examples, gasket 904 may be referred to as a sealing gasket to make an airtight seal between carrier frame 404 and a chassis base of an information handling system, such as chassis base 304 of information handling system 100 shown in FIG. 3. In an example, gasket 904 may be proud of I/O connector 312, such that the gasket extends beyond the edge of the I/O connector. In certain examples, gasket 904 may be included on carrier frame 302 when an information handling system, such as information handling system 100 of FIG. 1, has a hyperbaric thermal system.

Referring now to FIG. 10, chassis base 304 includes walls 1002 and 1004. In an example, wall 1002 may be an outer wall of chassis base 304 and extend around the entire perimeter of the chassis base. Wall 1004 may be in physical communication with an inner surface of wall 1002 and include a gap 1010 to enable gasket 904 to be placed in physical communication with wall 1002. In an example, the thickness of wall 1004 may be slightly less than the thickness of gasket 904. In this example, when carrier frame 302 is inserted into chassis base 304, gasket 904 may compress to create the airtight seal between the carrier frame and the chassis base.

Referring now to FIG. 11, a cross section along line A-A in FIG. 10 is illustrated to show the physical interaction between gaskets 902 and 904 and chassis frame 304. In an example, chassis frame includes a top panel 1102. When carrier frame 302 is inserted within chassis base 304 and top panel 1102 is installed, gasket 904 may compress and create a sealing location 1110. In an example, scaling location 1110 may extend along the surface of gasket 904 wherever the gasket is in physical communication with top panel 1102 and wall 1004.

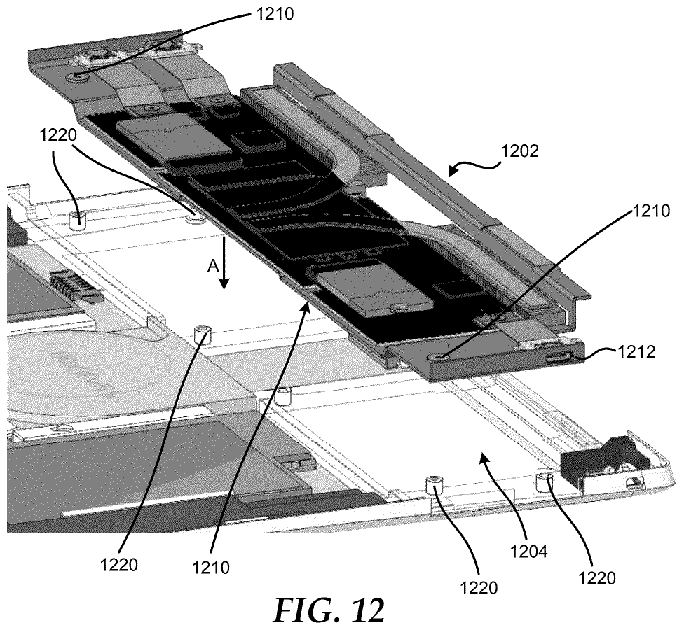

FIG. 12 illustrates a carrier frame 1202 and a chassis base 1204 of an information handling system, such as information handling system 100 of FIG. 1, according to at least one embodiment of the present disclosure. Carrier frame 1202 may be substantially similar to carrier frame 302 of FIG. 3. However, carrier frame 1202 may include mounting components 1210 and a side wall 1212 instead of mounting components 408 and 410 of carrier frame 302 shown in FIG. 4. Chassis base 1204 may be substantially similar to chassis base 304 of FIG. 3. However, chassis base 1204 may include mounting components 1220 instead of mounting components 418 and 420 of chassis base 304 shown in FIG. 4.

In an example, mounting components 1210 and 1220 may be snap fit components, such that each different one of mounting components 1210 may snap fit within a corresponding different one of mounting components 1220. In certain examples, carrier frame 1202 may drop straight down into chassis base 1204. When carrier frame 1202 is fully inserted within chassis base 1204, mounting components 1210 may snap fit within mounting components 1220 to securely connect the carrier frame to the chassis base. While only a couple of fastening a carrier frame to a chassis base of an information handling system, the carrier frame and chassis base may include other types of mounting components.

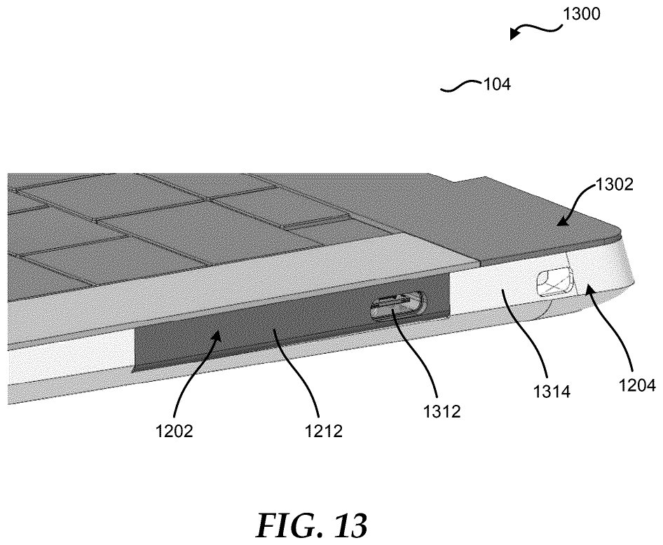

FIG. 13 illustrates a portion an information handling system 1300 according to at least one embodiment of the present disclosure. Information handling system 1300 may be substantially similar to information handling system 100 of FIG. 1. Information handling system 1300 includes a base 1302, an I/O connector 1312, and a wall 1314. I/O connector 1312 may be substantially similar to I/O connector 312 of FIG. 3.

When carrier frame 1202 is inserted within chassis base 1204, wall 1212 of the carrier frame may form part of wall 1314 of the chassis base. In an example, wall 1212 may form part of wall 1314 in the location of I/O connector 1312. While only one side of information handling system 1300 is illustrated and described herein, carrier frame 1202 may have additional walls to form part of wall 1314 of chassis base 1204.

While an exemplary carrier frame 302 has been described herein, the carrier frame may be changed slightly without varying from the scope of this disclosure. For example, carrier frame 302 may slide into chassis base 304 from a side or from the back of the chassis base. In this example, post mounting components 408 and 420 and slot mounting components 410 and 418 may be aligned to interconnect based on the direction carrier frame 302 is inserted within chassis base 304.

In an example, carrier frame 302 may form the entire rear wall of chassis base 302. In this example, carrier frame 302 may include multiple different thermal solutions over those described herein. In an example, components on carrier frame 302 may be completely sealed on the carrier frame by protective shield 702, such that an end-user may not have access to these components. In this example, the entire carrier frame 302 may be replaced when a user decides to update components on the carrier frame.

In certain examples, protective shield 702 may cover certain components, such as storage devices, for security purposes, but allow access to these components with a special tool or extra steps. For example, the extra steps may include unlocking a security door on protective shield 702, removing a portion of the protective shield, or the like. In an example, protective shield 702 may be formed of multiple pieces, which may or may not be the same material. Protective shield 702 may share functions with other components on carrier frame 302, such as radio frequency (RF) protection, thermal ducting, heat spreading, or the like. In certain examples, motherboard PCBA 802 may have multiple boards contained on carrier frame 302, such as a small main board, multiple I/O boards, or the like.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A carrier frame for an information handling system, the printed circuit board assembly comprising:
a main portion having a top surface and a bottom surface;
first and second wing portions extending from opposite ends of the main portion, the first and second wing portions have the top surface and the bottom surface, wherein the system motherboard and the other components are in physical communication with the top surface; and
a plurality of mounting components extending from the bottom surface, wherein the mounting components securely and removably connect the carrier frame within the information handling system.

2. The carrier frame of claim 1, further comprising: a protective shield in physical communication with the system motherboard and other components, wherein the protective shield prevents physical access to the system motherboard and the other components on the carrier frame.

3. The carrier frame of claim 1, wherein the carrier frame further comprises: a connector to provide electrical communication from the information handling system to the system motherboard and to the other components.

4. The carrier frame of claim 1, wherein the mounting components are snap fit connectors.

5. The carrier frame of claim 1, wherein the mounting components includes first and second groups of mounting components, wherein the first group of mounting components is a first plurality of slots, wherein the second group of mounting components is a first plurality of posts.

6. The carrier frame of claim 5, wherein each one of the first slots receives a respective one of a second plurality of posts within the information handling system.

7. The carrier frame of claim 5, wherein each one of the first posts interfaces with a respective one of a second plurality of slots within the information handling system.

8. The carrier frame of claim 1, wherein a section of the main portion extends from the top surface to form a portion of a chassis of the information handling system.

9. The carrier frame of claim 1, wherein a section of the first wing portion extends from the top surface to form a portion of a chassis of the information handling system.

10. The carrier frame of claim 1, further comprising: a heat sink plate, a plurality of heat pipes, and a plurality of heat sinks.

11. An information handling system comprising:
a chassis base including:
a bottom surface; and
first, second, third and fourth walls; and
a carrier frame in physical communication with the chassis base, the carrier frame configured to hold a system motherboard and other components, the carrier frame includes:
a main portion having a top surface and a bottom surface;
first and second wing portions extending from opposite ends of the main portion, the first and second wing portions have the top surface and the bottom surface, wherein the system motherboard and the other components are in physical communication with the top surface; and
a plurality of mounting components extending from the bottom surface, wherein the mounting components securely and removably connect the carrier frame to the chassis base.

12. The information handling system of claim 11, further comprising: a protective shield in physical communication with the system motherboard and other components.

13. The information handling system of claim 11, further comprising:
a first connector of the carrier; and
a second connector, wherein the first and second connectors provide electrical communication from the information handling system to the system motherboard and to the other components.

14. The information handling system of claim 11, wherein the mounting components are snap fit connectors.

15. The information handling system of claim 11, wherein the mounting components includes first and second groups of mounting components, wherein the first group of mounting components is a first plurality of slots, wherein the second group of mounting components is a first plurality of posts.

16. The information handling system of claim 15, wherein each one of the first slots receives a respective one of a second plurality of posts mounted on the chassis base.

17. The information handling system of claim 15, wherein each one of the first posts interfaces with a respective one of a second plurality of slots mounted on the chassis base.

18. The information handling system of claim 11, wherein a section of the main portion extends from the top surface to form a portion of the chassis base.

19. An information handling system comprising:
a chassis base including:
a bottom surface; and
first, second, third and fourth walls;
a first connector;
a carrier frame in physical communication with the chassis base, the carrier configured to hold a system motherboard and other components, the carrier frame includes:
a main portion having a top surface and a bottom surface;
first and second wing portions extending from opposite ends of the main portion, the first and second wing portions have the top surface and the bottom surface, wherein the system motherboard and the other components are in physical communication with the top surface;
a plurality of mounting components extending from the bottom surface, wherein the mounting components securely and removably connect the carrier frame to the chassis base; and
a second connector, wherein the first and second connectors provide electrical communication from the information handling system to the system motherboard and to the other components; and
a protective shield in physical communication with the system motherboard and other components.

20. The information handling system of claim 19, wherein a section of the main portion extends from the top surface to form a portion of the chassis base.
